(19) United States
(12) Patent Application Publication
(10) Pub. No.: US 2008/0180988 A1
(43) Pub. Date: Jul. 31, 2008

(54) DIRECT WRITING METHOD OF MAGNETIC MEMORY CELL AND MAGETIC MEMORY CELL STRUCTURE

(75) Inventors: Yuan-Jen Lee, Taipei County (TW); Chien-Chung Hung, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: INDUSTRIAL TECHNOLOGY RESEARCH INSTITUTE, Hsinchu (TW)

(21) Appl. No.: 11/754,308

(22) Filed: May 27, 2007

(30) Foreign Application Priority Data
Jan. 29, 2007 (TW) 96103233

(51) Int. Cl. G11B 5/147; G11C 11/00

(52) U.S. Cl. 365/158

(57) ABSTRACT

A direct writing method of a magnetic memory cell is provided. The magnetic memory cell includes a magnetic free stacked layer having a bottom and a top ferromagnetic layer. The bottom and top ferromagnetic layers respectively have a bi-directional easy axis in substantially the same direction. The method includes applying a first magnetic field in the direction of the bi-directional easy axis and performing a writing operation. To write a first memory state, a second magnetic field is supplied at a first side of the bi-directional easy axis with a first including angle. To write a second memory state, a third magnetic filed is supplied at a second side of the bi-directional easy axis with a second including angle. At least one of the bottom and top ferromagnetic layers has a unidirectional easy axis in different direction from the bi-directional easy axis.

### CROSS-REFERENCE TO RELATED APPLICATION

This application claims the priority benefit of Taiwan application serial no. 96103233, filed on Jan. 29, 2007. All disclosure of the Taiwan application is incorporated herein by reference.

### BACKGROUND OF THE INVENTION

1. Field of the Invention

The present invention relates to a writing method of a magnetic memory cell and a magnetic memory cell structure.

2. Description of Related Art

Magnetic memory, such as magnetic random access memory (MRAM), is also a non-volatile memory which has such advantages as non-volatility, high density, high read/write speed, and being radiation proof. Data of 0 or 1 is recorded in a magnetic memory cell through the magnetroresistance produced by arranging the magnetizations of the magnetic materials adjacent to a tunnel insulation layer in parallel or anti-parallel. While writing a data into a magnetic memory, a memory cell at the intersection of the magnetic fields induced by two current lines, for example, a bit line (BL) and a write word line (WWL), is usually selected, and meanwhile, the magnetroresistance of the memory cell is changed by changing the direction of the magnetization of a free layer. While reading a data from the magnetic memory, a current is conducted into the selected memory cell, and the digital value of the data can be determined according to the detected resistance of the memory cell.

FIG. 1 is a schematic diagram of a magnetic memory cell. Referring to FIG. 1, to access a magnetic memory cell, appropriate currents are conducted into two crossing current lines 100 and 102, wherein the current lines 100 and 102 may be referred as WWLs or BLs according to the operation manner thereof. After conducting with currents, the two current lines produce two magnetic fields in different directions, so that a magnetic field of required intensity and direction is obtained and supplied on the magnetic memory cell 104. The magnetic memory cell 104 is of stacked layer structure and which includes a magnetic pinned layer having a fixed magnetization or a total magnetic moment in a predetermined direction. The data is read according to the magnitude of the magnetroresistance. In addition, the data stored in the memory cell can be read through the output electrodes 106 and 108. The operation details of magnetic memory should be understood by those ordinarily skilled in the art therefore will not be described herein.

FIG. 2 illustrates the recording mechanism of a magnetic memory. In FIG. 2, the magnetic pinned layer 104a has a fixed magnetic moment direction 107. The magnetic free layer 104c is disposed above the magnetic pinned layer 104a, and the two layers are isolated by an insulation layer 104b. The magnetic free layer 104c has a magnetic moment direction 108a or 108b. If the magnetic moment direction 108a is parallel to the magnetic moment direction 107, the magnetroresistance produced may represent a binary data “0”; otherwise, if the magnetic moment direction 108b is anti-parallel to the magnetic moment direction 107, the magnetroresistance produced may represent a binary data “1”.

Generally, access error to the single magnetic free layer 104c may occur. To resolve this problem and to reduce interference to adjacent memory cells while writing data, conventionally a magnetic free stacked layer 166 having a FM/M/FM three-layer structure is used to replace the single layer of ferromagnetic material, and the structure thereof is illustrated in FIG. 3. The two ferromagnetic metal layers 150 and 154 above and below the non-magnetic metal layer 152 are anti-parallel to each other and form a close magnetic field line. The magnetic pinned stacked layer 168 at the bottom is isolated from the magnetic free stacked layer 166 by a tunnel barrier layer (T) 156. The magnetic pinned stacked layer 168 includes a top pinned layer (TP) 158, a non-magnetic metal layer 160, and a bottom pinned layer (BP) 162. The top pinned layer 158 and the bottom pinned layer 162 have fixed magnetizations. In addition, a base layer 164, for example, an anti-ferromagnetic layer, is disposed at the bottom.

As to the magnetic free stacked layer 166 of three-layer structure, the magnetic anisotropic axes of the BL and the WWL corresponding to the free stacked layer 166 form an including angle of 45°, and the direction of the magnetic anisotropic axis thereof is the direction of easy axis. Accordingly, the BL and the WWL respectively supply a magnetic field having an angle of 45° to the easy axis to the free stacked layer 166 successively in order to rotate the magnetization of the free stacked layer 166. The data stored in the memory cell is determined by the directions of the two magnetizations of the ferromagnetic metal layer 154 and the top pinned layer 158.

Besides changing the free layer into a three-layer structure, conventionally, a toggle operation mode is also provided for rotating the magnetization of the free layer. FIG. 4 illustrates the effect of an external magnetic field to the three-layer structure. Referring to FIG. 4, the bold arrow represents the external magnetic field, and the length thereof denotes the intensity of the external magnetic field. The two thin arrows represent the magnetization directions of the two ferromagnetic layers of the free stacked layer. The directions of the two magnetizations are not changed when the external magnetic field is very small. The two magnetizations form a angle when the external magnetic field is increased to a certain value. The two magnetizations are along the direction of the external magnetic field when the external magnetic field is overlarge. The toggle mode operation belongs to the second situation described above.

FIG. 5 is a timing diagram of the external magnetic field in toggle mode. Referring to FIG. 5, H₁ and H₂ represent the directions of two external magnetic fields which respectively form an angle of 45° with the easy axis, and the two arrows in the ellipse represent the directions of the two magnetizations. During time section to, there is no external magnetic field supplied, thus, the two magnetizations are in the direction of the easy axis. Next, the magnetic fields of H₁ and H₂ are turned on along with the timing illustrated in FIG. 5, so that total magnetic fields of different time sections (t₁-t₃) are obtained for rotating the directions of the two magnetizations. During time section t₄, the magnetic fields are stopped being supplied, and the directions of the two magnetizations are reversed once. As described above, the data stored in the memory cell is changed.

In addition, the write current is still quite high in the toggle operation mode, thus, a magnetic bias field is also brought into the conventional technique. FIG. 6 illustrates a conventional technique for reducing operation current. Referring to FIG. 6, the basic structure of the memory cell is similar to that illustrated in FIG. 3, and the major difference between the two is that the total magnetic moment of the bottom pinned layer 162 is increased corresponding to that of the top pinned layer 158, for example, the thickness of the bottom pinned layer 162 is increased. A fringe magnetic field is produced since the total magnetic moments of the bottom pinned layer 162 and the top pinned layer 158 are not balanced. The fringe magnetic field produces a magnetic field bias 184 to the free stacked layer 166 which moves the toggle operation region in the first quadrant to the zero point of the magnetic field, and eventually the toggle operation region is reduced into a distance 186. Accordingly, the write current which produces the write magnetic field is reduced since the required write magnetic field is small.

As described above, the mechanism for writing a data into a corresponding magnetic memory cell has been improved; however, according to the conventional operation manner, the existing data stored in the magnetic memory cell still has to be read during time section t₂ and the data is written only when the existing data is different from the data to be written. In such conventional writing operation, since an existing data has to be read first, the speed for reading data is relatively slow, and accordingly, the conventional writing operation is slow. Therefore, how to increase the speed of writing operation is still the concerning issue in development.

### SUMMARY OF THE INVENTION

Accordingly, the present invention is directed to a direct writing method of a magnetic memory cell, wherein a data can be directly written into the magnetic memory cell without reading the content of the magnetic memory cell first.

The present invention provides a direct writing method of a magnetic memory cell. The magnetic memory cell includes a magnetic free stacked layer having a bottom ferromagnetic layer and a top ferromagnetic layer. The bottom ferromagnetic layer and the top ferromagnetic layer respectively have a bi-directional easy axis in substantially the same direction. The direct writing method includes supplying a first magnetic field in the direction of the bi-directional easy axis and performing a writing operation. When a first memory state is to be written, a second magnetic field, instead of the first magnetic field, is supplied at a first side of the bi-directional easy axis with a first including angle. When a second memory state is to be written, a third magnetic field, instead of the first magnetic field, is supplied at a second side of the bi-directional easy axis with a second including angle.

The present invention further provides a direct writing method of a magnetic memory cell which is suitable for accessing a magnetic memory cell. The magnetic memory cell includes a magnetic free stacked layer, and the magnetic free stacked layer is composed of a bottom ferromagnetic layer, a non-magnetic intermediate layer, and a top ferromagnetic layer which are stacked together. The bottom ferromagnetic layer and the top ferromagnetic layer respectively have a bi-directional easy axis in substantially the same direction, wherein an operational magnetic field is produced by adding a first magnetic field and a second magnetic field which are nearly perpendicular to each other and respectively form an angle of about 45° with the bi-directional easy axis.

According to the direct writing method described above, the first magnetic field is supplied when the operational magnetic field is about to write a first memory state, wherein the first magnetic field is a first magnetic field level waveform having a first pulse with a first width. In addition, the second magnetic field is supplied substantially at the same time, wherein the second magnetic field is a second magnetic field level waveform having a second pulse with a second width. The first width is smaller than the second width, and the first pulse and the second pulse have substantially the same magnetic field intensity. The operational magnetic field returns to a low magnetic field level after the second pulse elapses.

The first magnetic field is supplied when the operational magnetic field is about to write a second memory state, wherein the first magnetic field is a third magnetic field level waveform having a third pulse of a third width. In addition, the second magnetic field is supplied substantially at the same time, wherein the second magnetic field is a fourth magnetic field level waveform having a fourth pulse of a fourth width. The third width is greater than the fourth width, and the third pulse and the fourth pulse have substantially the same magnetic field intensity. The operational magnetic field returns to the low magnetic field level after the third pulse elapses.

The present invention provides a magnetic memory cell structure including a magnetic pinned stacked layer, a tunnel barrier layer, a magnetic free stacked layer, and a first anti-ferromagnetic layer. The tunnel barrier layer is disposed on the magnetic pinned stacked layer. The magnetic free stacked layer is disposed above the tunnel barrier layer, wherein the magnetic free stacked layer includes a bottom ferromagnetic layer and a top ferromagnetic layer which respectively have a bi-directional easy axis in substantially the same direction. The first anti-ferromagnetic layer is adjacent to one of the bottom and the top ferromagnetic layer and is referred as a first adjacent ferromagnetic layer, wherein a magnetic dipole alignment line of the first anti-ferromagnetic layer forms a first including angle with the bi-directional easy axis for producing a first unidirectional easy axis on the first adjacent ferromagnetic layer.

In order to make the aforementioned and other objects, features and advantages of the present invention comprehensible, preferred embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a magnetic memory cell.

FIG. 2 illustrates the recording mechanism of a magnetic memory.

FIG. 3 is a cross-sectional view of a conventional magnetic memory cell.

FIG. 4 illustrates the effect of an external magnetic field to a free layer of three-layer structure.

FIG. 5 is a timing diagram of an external magnetic field in toggle mode.

FIG. 6 illustrates a conventional technique for reducing an operation current.

FIG. 7 illustrates a first state magnetic field writing waveform according to an embodiment of the present invention.

FIG. 8 illustrates a second state magnetic field writing waveform according to an embodiment of the present invention.

FIG. 9 illustrates another situation of an external magnetic field twisting a magnetization.

FIG. 10 illustrates the structure of a magnetic memory cell according to an embodiment of the present invention.

FIG. 11 illustrates a situation of an external magnetic field twisting a magnetization according to an embodiment of the present invention.

FIG. 12 illustrates the waveform of another operational magnetic field according to an embodiment of the present invention.

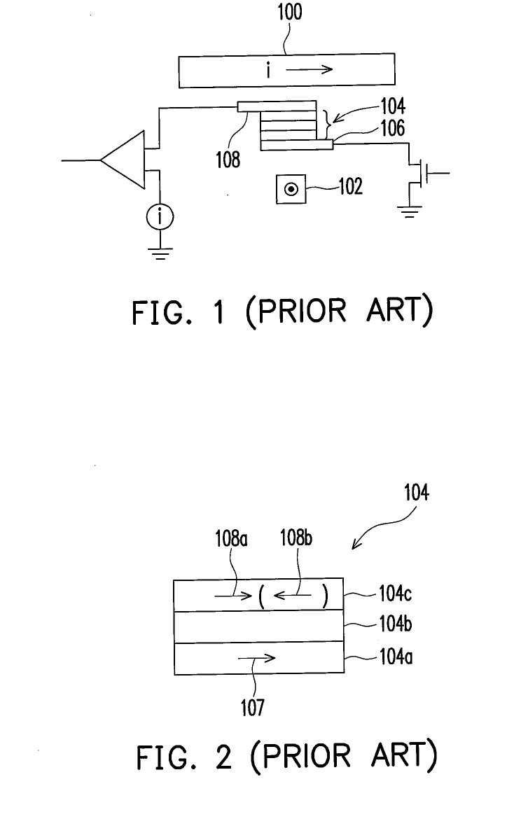

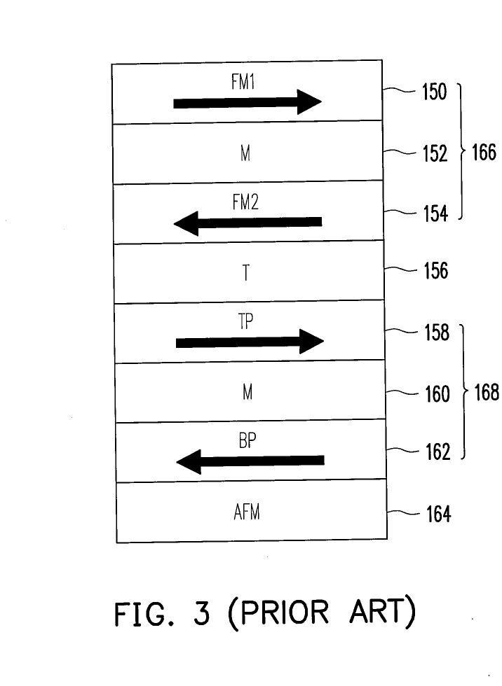

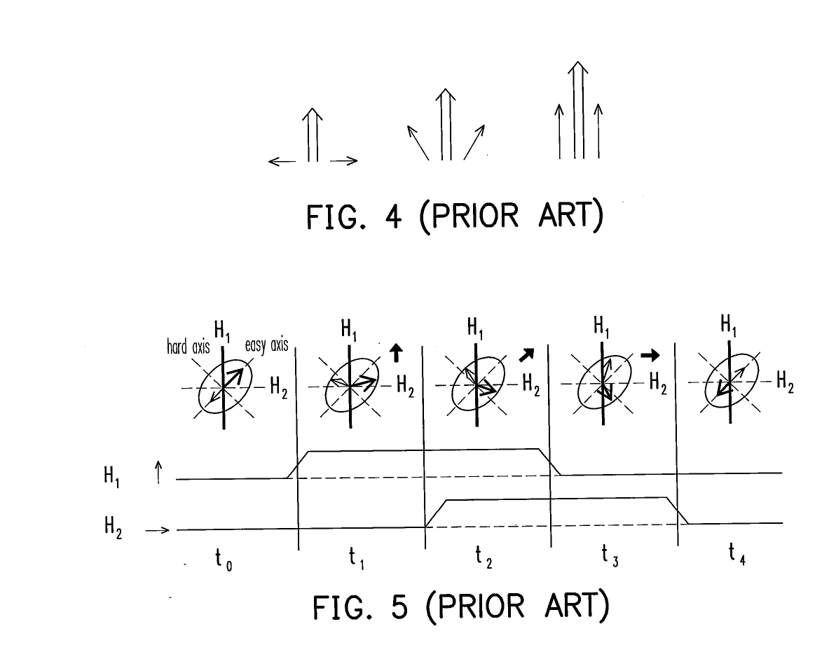

### DESCRIPTION OF EMBODIMENTS

The present invention provides a direct writing method of a magnetic memory cell, wherein a data can be directly written into the magnetic memory cell without reading the content of the magnetic memory cell first.

The present invention also provides a magnetic memory cell structure. A magnetic free stacked layer in the magnetic memory cell structure may include a bottom ferromagnetic layer and a top ferromagnetic layer which respectively have a bi-directional easy axis in substantially the same direction. A first anti-ferromagnetic layer is disposed adjacent to one of the bottom and the top ferromagnetic layer and is referred as a first adjacent ferromagnetic layer, wherein a magnetic dipole alignment line of the first anti-ferromagnetic layer forms a first including angle with the bi-directional easy axis for producing a first unidirectional easy axis on the first adjacent ferromagnetic layer.

In addition, the magnetic memory cell structure may further include a second anti-ferromagnetic layer disposed adjacent to the other one of the bottom and the top ferromagnetic layer and is referred as a second adjacent ferromagnetic layer, wherein a magnetic dipole alignment line of the second anti-ferromagnetic layer forms a second including angle with the bi-directional easy axis for producing a second unidirectional easy axis on the second adjacent ferromagnetic layer. The first unidirectional easy axis and the second unidirectional easy axis have different anisotropic intensities.

Some embodiments of the present invention will be described below; however, these embodiments are not intended for restricting the scope of the present invention.

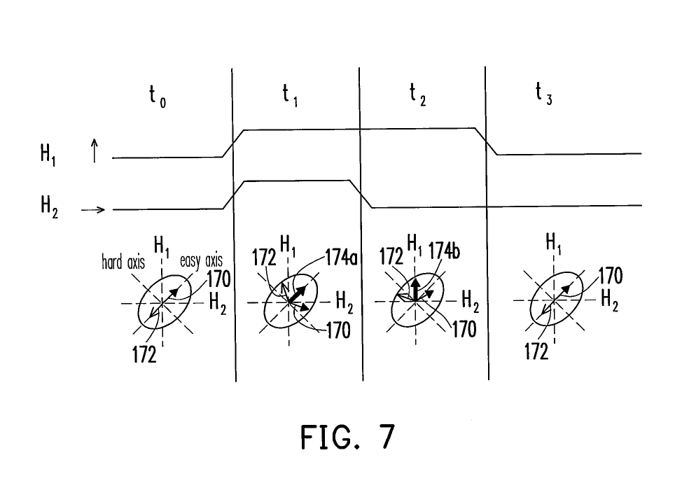

FIG. 7 illustrates a first state magnetic field writing waveform according to an embodiment of the present invention. Referring to FIG. 7, during time section to, the intensities of the magnetic fields H₁ and H₂ are 0, namely, there is no external magnetic field supplied during the initial stage. Besides, the top ferromagnetic layer has a magnetization 170, the bottom ferromagnetic layer has a magnetization 172, and the two are substantially on the easy axis but are anti-parallel to each other. During time section t₁, the magnetic fields H₁ and H₂ are both turned on, preferably, the magnetic fields H₁ and H₂ have the same intensity, so that the total magnetization 174a is on the easy axis. Here the magnetizations 170 and 172 reach equilibrium with the total magnetization 174a. Next, during time section t₂, the magnetic field H₂ is turned off, namely, only the magnetic field H₁, i.e. the magnetic field 174b, is supplied. During this time section t₂, the two magnetizations 170 and 172 are rotated anti-clockwise corresponding to the magnetic field 174b. During time section t₃, the magnetic field H₁ is also turned off, namely, there is no external magnetic field supplied, thus, the two magnetizations 170 and 172 fall in a stable state, for example, a first state denoting “0”. In the present embodiment, the first state is the forward direction of the magnetization 170 along the easy axis.

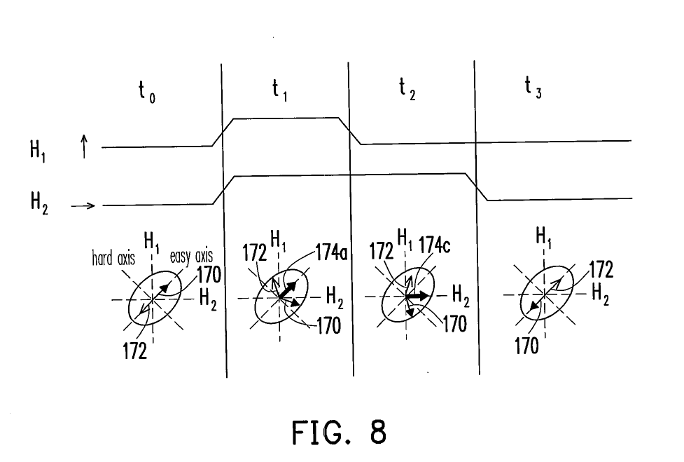

On the other hand, the writing magnetic field waveform is different if a second state is to be written. FIG. 8 illustrates a second state magnetic field writing waveform according to an embodiment of the present invention. Referring to FIG. 8, the situation during time sections t₀ and t₁ are the same as those illustrated in FIG. 7, however, during time section t₂, the magnetic field H₁ is turned off, namely, only the magnetic field H₂, i.e. the magnetic field 174c, is supplied. The two magnetizations 170 and 172 are rotated clockwise corresponding to the magnetic field 174c. During time section t₃, the magnetization 170 is closer to the backward direction of the easy axis while the magnetization 172 is closer to the forward direction of the easy axis. Thus, the directions of the magnetizations 170 and 172 are reversed to the directions thereof during time section t₃ in FIG. 8 when there is no external magnetic field supplied. In other words, it may be referred as the second state when the magnetization 170 is in the backward direction of the easy axis. Accordingly, the desired second state, which may denote “1”, is written into the magnetic memory cell according to the magnetic field waveform in FIG. 8. It can be understood that the first and the second state here are only used for distinguishing two different states, while the actual contents thereof are not limited by the present embodiment. For example, foregoing first state may also be referred as the second state while foregoing second state may also be referred as the first state.

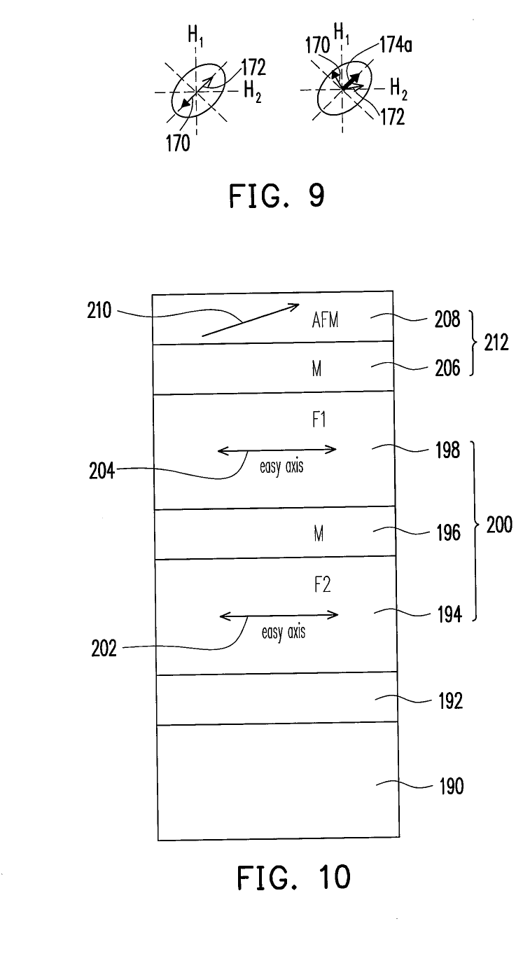

Generally speaking, regarding the operational magnetic field waveform described above, the first or the second state can be written as expected. However, the initial state may not be the same as that illustrated in the figure during time section to, or the magnetizations 170 and 172 are already aberrant from the easy axis initially, which may cause the state during time section t₁ unstable and accordingly writing error may occur. Another embodiment is illustrated in FIG. 9 and which will be described below. Referring to FIG. 9, it is assumed that during time section t₀, the magnetization 170 is along the backward direction of the easy axis. During time section t₁, even though the external magnetic field 174a is along the forward direction of the easy axis, the magnetizations 170 and 172 reach equilibrium when the magnetization 172 is closer to the direction of the magnetic field H₂. For example, a first state is to be written with the magnetic field waveform in FIG. 7, but eventually the second state is written mistakenly.

The present invention ensures the state stability during time section t₁ by providing a magnetic memory cell structure. In specific, the same state during time section t₁ is ensured regardless of what the initial state is, so that the magnetizations 170 and 172 can be rotated subsequently as expected. FIG. 10 is a diagram of a magnetic memory cell structure according to an embodiment of the present invention.

Referring to FIG. 10, in the present embodiment, the magnetic memory cell structure includes a magnetic pinned stacked layer 190, a tunnel barrier layer 192, a magnetic free stacked layer 200, and an anti-ferromagnetic layer 212. The tunnel barrier layer 192 is disposed on the magnetic pinned stacked layer 190. The magnetic free stacked layer 200 is disposed above the tunnel barrier layer 192, wherein the magnetic free stacked layer 200 includes a bottom ferromagnetic layer 194, a metal layer 196, and a top ferromagnetic layer 198. The bottom ferromagnetic layer 194 and the top ferromagnetic layer 198 respectively have a bi-directional easy axis 202 and a bi-directional easy axis 204 in substantially the same direction. In the present embodiment, an anti-ferromagnetic layer 208 is disposed adjacent to the top ferromagnetic layer 198. However, generally speaking, the anti-ferromagnetic layer 208 may be disposed adjacent to the bottom ferromagnetic layer or the top ferromagnetic layer. There may be two anti-ferromagnetic layers 208 respectively disposed adjacent to the bottom ferromagnetic layer 194 and the top ferromagnetic layer 198. Besides, the anti-ferromagnetic layer 208 may form a stacked layer 212 with a metal layer 206.

It should be noted here that an easy axis direction 210 of the anti-ferromagnetic layer 208 forms an including angle with the bi-directional easy axis 204 for producing a unidirectional easy axis on the adjacent ferromagnetic layer 198. In other words, the magnetization of the ferromagnetic layer 198 tends to fall in the direction of the unidirectional easy axis during time section t₁.

Since the anti-ferromagnetic layer 208 produces a unidirectional easy axis, it is ensured that the magnetization direction of the ferromagnetic layer 198 will not be affected by the initial position thereof and the magnetization of the ferromagnetic layer 198 can be rotated subsequently as expected. As shown in FIG. 11, when the magnetic field 174a is on the bi-directional easy axis, the magnetization 170 of the ferromagnetic layer 198 is at the left side.

Generally speaking, the including angle between the easy axis direction 210 and the bi-directional easy axis 204 is preferably 45°. However, it is acceptable as long as the including angle is substantially smaller than 90°. According to some experiments, the including angle can still work properly at 60°.

In addition, it is very difficult to turn on the magnetic fields H₁ and H₂ at the same time during time section t₁. However, also according to some experiments, certain difference between the turn-on times of the magnetic fields H₁ and H₂ is acceptable. For example, there is still an operation region at 2 ns for writing data correctly. In other words, the direct writing method provided by the present invention has certain tolerance in fabricating process and operation condition.

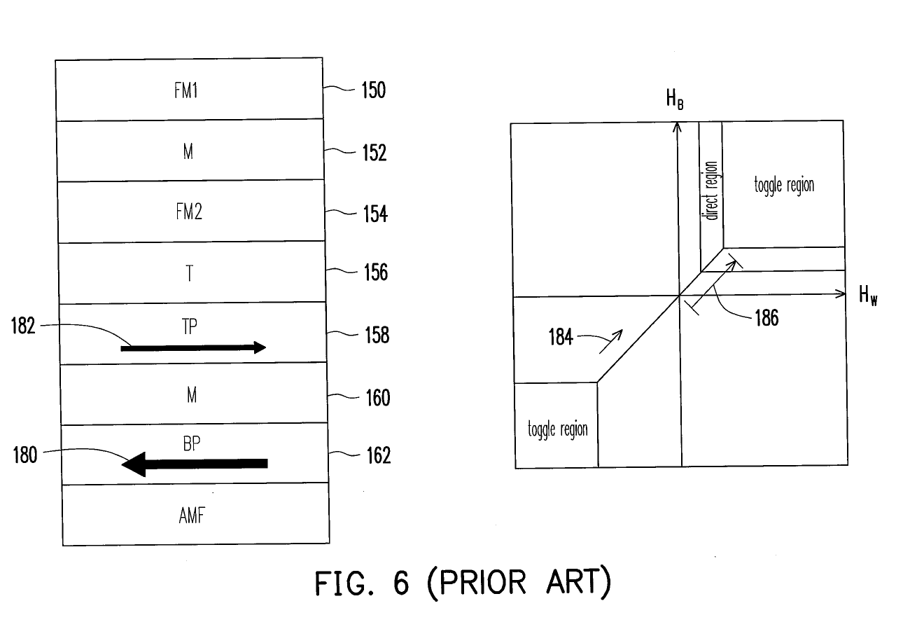

Moreover, as illustrated in FIG. 6, the magnetic field bias provided for reducing operation current or any other magnetic field bias may also be integrated with the magnetic memory cell structure in the present invention without departing the spirit of the present invention.

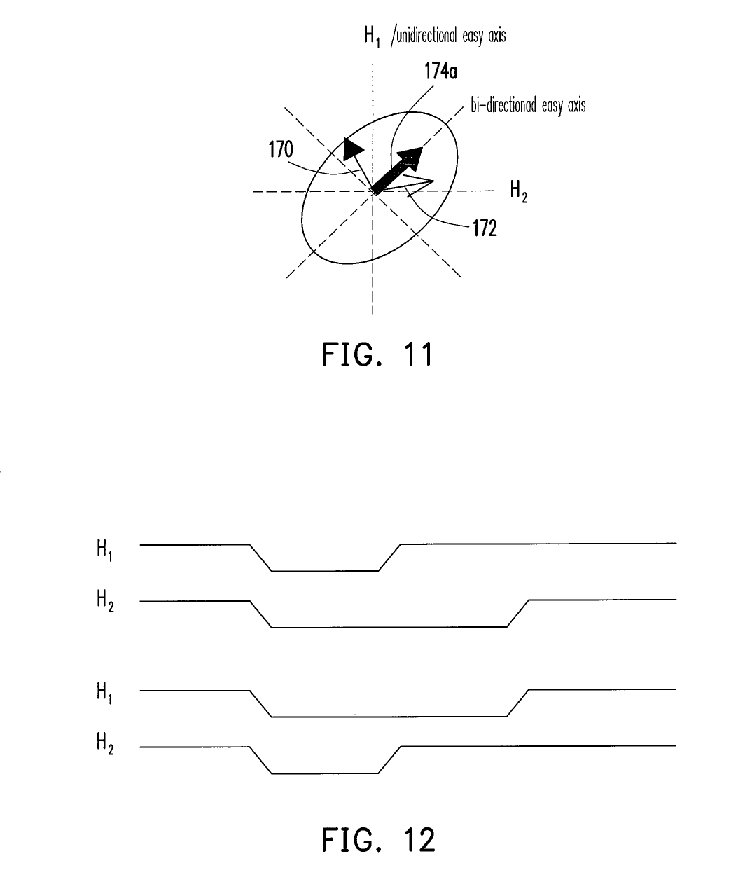

Furthermore, the magnetic fields H₁ and H₂ in FIG. 7 and FIG. 8 are positive values, and the operation is carried out in the first quadrant. However, the magnetic fields H₁ and H₂ may also provide the same performance and result in the third quadrant under the same conditions, namely, the magnetic fields H₁ and H₂ may be negative values, as illustrated in FIG. 12.

According to embodiments of the present invention, the data writing operation is sped up by skipping the conventional operation of reading the existing data in the memory cell. Moreover, a unidirectional easy axis having an appropriate including angle with the bi-directional easy axis is further produced in the free ferromagnetic layer to increase the accuracy in the data writing operation. The unidirectional easy axis urges the magnetizations to stay in the same state during time section t₁, thus, the data can be written in the memory cell correctly in the subsequent writing operation.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A direct writing method of a magnetic memory cell, wherein the magnetic memory cell comprises a magnetic free stacked layer, and the magnetic free stacked layer is composed of a bottom ferromagnetic layer, a non-magnetic intermediate layer, and a top ferromagnetic layer which are stacked together, and the bottom ferromagnetic layer and the top ferromagnetic layer respectively have a bi-directional easy axis in substantially a same direction, the direct writing method comprising:
supplying a first magnetic field in the direction of the bi-directional easy axis; and
performing a writing operation, writing a first memory state or a second memory state into the magnetic memory cell,
wherein when the writing operation is to write the first memory state, following steps are performed:
supplying a second magnetic field, instead of the first magnetic field, at a first side of the bi-directional easy axis with a first angle; and
stopping supplying the second magnetic field,
wherein when the writing operation is to write the second memory state, following steps are performed:
supplying a third magnetic field, in stead of the first magnetic field, at a second side of the bi-directional easy axis with a second angle, wherein the first side and the second side are opposite to each other; and
stopping supplying the third magnetic field.

2. The direct writing method as claimed in claim 1, wherein the first angle and the second angle are substantially the same and smaller than 90°.

3. The direct writing method as claimed in claim 2, wherein the first angle and the second including angel are substantially close to 45°.

4. The direct writing method as claimed in claim 1, wherein one of the bottom ferromagnetic layer and the top ferromagnetic layer of the magnetic memory cell has a unidirectional easy axis, and the unidirectional easy axis forms an including angle with the bi-directional easy axis.

5. The direct writing method as claimed in claim 4, wherein the including angle is substantially smaller than 90°.

6. The direct writing method as claimed in claim 4, wherein the including angle is substantially close to 45°.

7. The direct writing method as claimed in claim 1, wherein the bottom ferromagnetic layer and the top ferromagnetic layer of the magnetic memory cell respectively have a unidirectional easy axis having different anisotropic intensities, and the unidirectional easy axes respectively form an including angle with the bi-directional easy axis.

8. The direct writing method as claimed in claim 7, wherein the including angles are substantially smaller than 90°.

9. The direct writing method as claimed in claim 8, wherein the including angles are substantially close to 45°.

10. The direct writing method as claimed in claim 7, wherein the first angle and the second angle are substantially the same and smaller than 90°.

11. The direct writing method as claimed in claim 10, wherein the first angle and the second angle are substantially close to 45°.

12. A direct writing method of a magnetic memory cell, the method being suitable for accessing a magnetic memory cell, wherein the memory cell comprises a magnetic free stacked layer, and the magnetic free stacked layer is composed of a bottom ferromagnetic layer, a non-magnetic intermediate layer, and a top ferromagnetic layer which are stacked together, and the bottom ferromagnetic layer and the top ferromagnetic layer respectively have a bi-directional easy axis in substantially a same direction, wherein an operational magnetic field is produced by adding a first magnetic field and a second magnetic field which are nearly perpendicular to each other and respectively form an angle close to 45° with the bi-directional easy axis, the direct writing method comprising:
performing following steps when the operational magnetic field is to write a first memory state:
supplying the first magnetic field, wherein the first magnetic field is a first magnetic field level waveform having a first pulse of a first width; and
supplying the second magnetic field at substantially the same time, wherein the second magnetic field is a second magnetic field level waveform having a second pulse of a second width, the first width is smaller than the second width, and the first pulse and the second pulse have substantially the same magnetic field intensity, the operational magnetic field returns to a low magnetic field level after the second pulse elapses; and
performing following steps when the operational magnetic field is to write a second memory state:
supplying the first magnetic field, wherein the first magnetic field is a third magnetic field level waveform having a third pulse of a third width; and
supplying the second magnetic field at substantially the same time, wherein the second magnetic field is a fourth magnetic field level waveform having a fourth pulse of a fourth width, the third width is greater than the fourth width, and the third pulse and the fourth pulse have substantially the same magnetic field intensity, the operational magnetic field returns to the low magnetic field level after the third pulse elapses.

13. The direct writing method as claimed in claim 12, wherein one of the bottom ferromagnetic layer and the top ferromagnetic layer of the magnetic memory cell has a unidirectional easy axis, and the unidirectional easy axis forms an including angle with the bi-directional easy axis.

14. The direct writing method as claimed in claim 13, wherein the including angle is substantially smaller than 90°.

15. The direct writing method as claimed in claim 13, wherein the including angle is substantially close to 45°.

16. The direct writing method as claimed in claim 12, wherein the bottom ferromagnetic layer and the top ferromagnetic layer of the magnetic memory cell respectively have a unidirectional easy axis of different anisotropic intensities, and the unidirectional easy axes respectively form an including angle with the bi-directional easy axis.

17. The direct writing method as claimed in claim 16, wherein the including angles are substantially smaller than 90°.

18. The direct writing method as claimed in claim 16, wherein the including angles are substantially close to 45°.

19. A magnetic memory cell structure, comprising:
a magnetic pinned stacked layer;
a tunnel barrier layer, disposed on the magnetic pinned stacked layer;
a magnetic free stacked layer, disposed above the tunnel barrier layer, wherein the magnetic free stacked layer comprises a bottom ferromagnetic layer and a top ferromagnetic layer respectively having a bi-directional easy axis of substantially a same direction; and
a first anti-ferromagnetic layer, disposed adjacent to one of the bottom ferromagnetic layer and the top ferromagnetic layer and referred as a first adjacent ferromagnetic layer, wherein a magnetic dipole alignment line of the first anti-ferromagnetic layer forms a first including angle with the bi-directional easy axis for producing a first unidirectional easy axis on the first adjacent ferromagnetic layer.

20. The magnetic memory cell structure as claimed in claim 19, wherein the first including angle is substantially smaller than 90°.

21. The magnetic memory cell structure as claimed in claim 19 further comprising a non-magnetic layer disposed between the first anti-ferromagnetic layer and the first adjacent ferromagnetic layer.

22. The magnetic memory cell structure as claimed in claim 19 further comprising a second anti-ferromagnetic layer disposed adjacent to the other one of the bottom ferromagnetic layer and the top ferromagnetic layer and referred as a second adjacent ferromagnetic layer, wherein a magnetic dipole alignment line of the second anti-ferromagnetic layer forms a second including angle with the bi-directional easy axis for producing a second unidirectional easy axis on the second adjacent ferromagnetic layer, and the first unidirectional easy axis and the second unidirectional easy axis have different anisotropic intensities.

23. The magnetic memory cell structure as claimed in claim 22, wherein the second including angle is substantially smaller than 90°.

24. The magnetic memory cell structure as claimed in claim 22 further comprising a non-magnetic layer disposed between the second anti-ferromagnetic layer and the second adjacent ferromagnetic layer.
